(19) United States
(12) Patent Application Publication
(10) Pub. No.: US 2020/0073493 A1
(43) Pub. Date: Mar. 5, 2020

(54) TOUCH DISPLAY DEVICE AND METHOD FOR MAKING TOUCH DISPLAY DEVICE

(71) Applicants: Interface Technology (ChengDu) Co., Ltd., Chengdu (CN); INTERFACE OPTOELECTRONICS (SHENZHEN) CO., LTD., Shenzhen (CN); GENERAL INTERFACE SOLUTION LIMITED, Zhunan (TW)

(72) Inventors: HSIAO-CHIEN CHEN, Zhunan (TW); CHIH-PENG CHANG, Zhunan (TW)

(21) Appl. No.: 16/236,547

(22) Filed: Dec. 30, 2018

(30) Foreign Application Priority Data
Sep. 5, 2018 (CN) 201811033098.5

(51) Int. Cl. G06F 3/044

(52) U.S. Cl. CPC G06F 3/044; H01L 27/323

(57) ABSTRACT

A touch display device of increased flexibility and reduced thickness includes a touch panel. The touch panel includes a substrate and a touch sensing layer formed on the substrate. The substrate is made of polyvinylidene fluoride. The present disclosure also provides a method for making such touch display device. The substrate of the touch display device of the present disclosure is made of polyvinylidene fluoride, which not only increases the flexibility of the touch display device, but also reduces the thickness of the touch display device.

### FIELD

The subject matter herein generally relates to touch display devices.

### BACKGROUND

Conventional touch display devices generally include a display panel, a touch panel, a polarizer, a cover, and other elements. A substrate for supporting sensing electrodes in the touch display device, such as glass, polyethylene terephthalate (PET), polyimine (PI), etc., may affect the flexibility of the touch display device. Moreover, different components in the touch display device need to be combined by different adhesive layers respectively, in which it makes reduce the thickness of the touch display device to be problematic.

Therefore, there is room for improvement in the art.

### BRIEF DESCRIPTION OF THE DRAWINGS

Implementations of the present technology will now be described, by way of embodiments, with reference to the attached figures.

FIG. 1 is a planar view of a touch display device according to a first embodiment of the present disclosure.

FIG. 2 is a cross-sectional view along line II-II of FIG. 1.

FIG. 3 is a planar view of a touch panel according to the first embodiment of the present disclosure.

FIG. 4 is a cross-sectional view of a touch panel according to an embodiment of the present disclosure.

FIG. 5 is a cross-sectional view of a touch panel according to an embodiment of the present disclosure.

FIG. 6 is a cross-sectional view of a touch display device according to a second embodiment of the present disclosure.

FIG. 7 is a cross-sectional view of a touch display device according to a third embodiment of the present disclosure.

FIG. 8 is a cross-sectional view of a touch display device according to a fourth embodiment of the present disclosure.

FIG. 9 is a flowchart of a method for manufacturing the touch display device of the fourth embodiment.

FIG. 10 is a flowchart of a method for manufacturing the touch display device of the first or the third embodiment.

FIG. 11 is a flowchart of a method for manufacturing the touch display device of the second embodiment.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein may be practiced without these specific details. In other instances, methods, procedures, and components have not been described in detail so as not to obscure the related relevant feature being described. Also, the description is not to be considered as limiting the scope of the embodiments described herein. The drawings are not necessarily to scale and the proportions of certain parts may be exaggerated to better illustrate details and features of the present disclosure.

The term “coupled” is defined as connected, whether directly or indirectly through intervening components, and is not necessarily limited to physical connections. The connection can be such that the objects are permanently connected or releasably connected. The term “comprising” when utilized, means “including, but not necessarily limited to”; it specifically indicates open-ended inclusion or membership in the so-described combination, group, series, and the like.

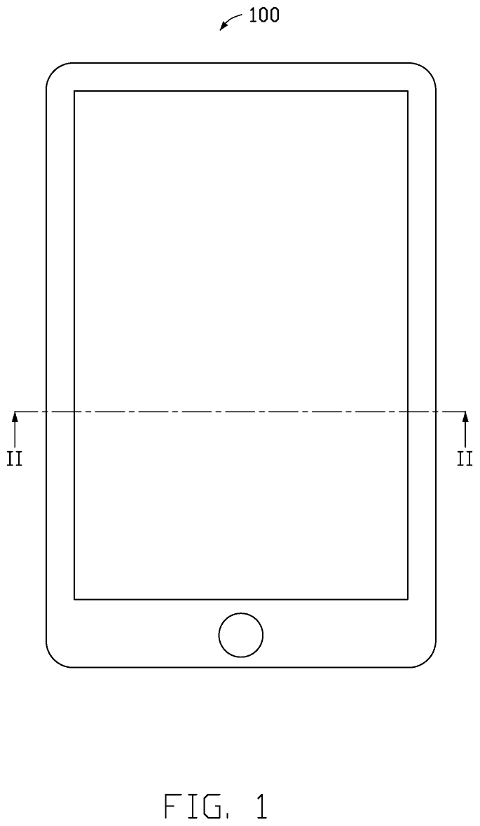

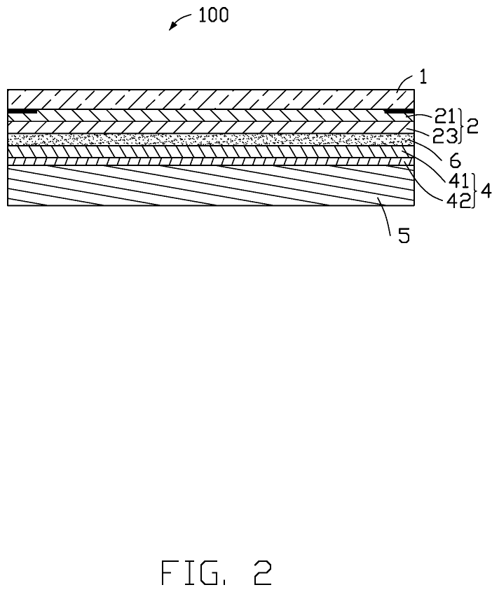

As shown in FIG. 1 and FIG. 2, a touch display device for a mobile phone 1 is disclosed. The mobile phone 1 includes a shell 10 having an opening 101 and a touch display device 100 having a touch function, the touch display device 100 is accommodated in the shell 10 and exposes a touch operation surface to the opening 101. The touch display device 100 of the present disclosure is not limited to being applied to the mobile phone 1, it can be applied to other electronic devices.

The touch display device 100 includes a cover 1, a linear polarizer 21, a phase retarder 23, a touch panel 4, and a display panel 5 which are sequentially stacked. However, the line polarizer 21, the phase retarder 23, the touch panel 4, and the display panel 5 are not limited to being stacked in order shown in FIG. 2. In this embodiment, the cover 1 is a flexible substrate.

As shown in FIG. 2, the touch panel 4 includes a touch sensing layer 41 and a substrate 42 supporting the touch sensing layer 41. The substrate 42 is made of polyvinylidene fluoride (PVDF). In an embodiment, the substrate 42 may be made of vinylidene chloride homopolymer or copolymer of vinylidene chloride with other small amounts of vinyl chloride-containing monomer. The substrate 42 can be directly coated on the surface of the display panel 5.

FIG. 2 shows macrostructure of the display panel schematically, the detail features of the display panel 5 are not shown, and the display panel further includes upper substrate, lower substrate, and display medium located between the upper substrate and the lower substrate (not shown).

The substrate 42 of the touch panel 4 is directly formed on a surface of the upper substrate of the display panel 5, such that the touch panel 4 and the display panel do not need to be combined by an adhesive layer. This allows some reduction in the thickness of touch display device 100. Further, the substrate 42 is made of PVDF, and its flexibility is greater than that of a substrate made of PET, PI, and so on. Conventional substrate made of PET and other materials are solid at normal temperatures (melting point is about 6-70° C.). The melting point of PVDF is about −30° C., it is in a molten state at normal temperatures, therefore, the substrate 42 made of PVDF can be formed on the surface of the display panel 5 by coating, printing, physical vapor deposition (PVD), or chemical vapor deposition (CVD).

In this embodiment, the PVDF in the molten state can be formed on the display panel 5 by coating, and cured to form the substrate 42 by heating or UV light. In addition to the characteristics of flexibility, the thickness of the touch panel 4 comprising the substrate 42 made of PVDF is also reduced. In this embodiment, the thickness of the touch panel 4 is less than 35 μm.

The line polarizer 21 and the phase retarder 23 are sequentially coated on the cover 11. The line polarizer 21 and the phase retarder 23 are structures for improving the display effect of the display panel 5. In this embodiment, the phase retarder 23 is a quarter-wavelength phase retarder, and the line polarizer 21 and the phase retarder 23 are configured to be a polarizing function layer 2. In other embodiments, the polarizing function layer 2 of the touch display device 100 may include only the linear polarizer 21.

In this embodiment, the linear polarizer 21 and the phase retarder 23 are directly coated on the cover 1 sequentially. The phase retarder 23 and the linear polarizer 21 may be directly coated on the cover 1 sequentially without using an adhesive layer, such that the thickness of the touch display device 100 can be reduced when combining the line polarizer 21, the phase retarder 23, and the cover 1. Further, since the linear polarizer 21 and the phase retarder 23 are formed by coating and curing a polarizing material and a phase retardation material, substrates or protective layers of the linear polarizer 21 and the phase retarder 23 can be omitted. Since the linear polarizer 21 includes only a polarizing material that realizes a polarizing function, the phase retarder 23 includes only a phase retarding material that realizes a phase delay function, and there is no need for using the substrates or the protective layers that affect the flexibility and thickness of the touch display device 100.

As shown in FIG. 2, the touch display device 100 further includes an adhesive layer 6 located between the polarizing function layer 2 and the touch sensing layer 41. In this embodiment, the adhesive layer 6 is located between the phase retarder 23 and the touch sensing layer 41. Since the substrate 42 of the touch panel 4 is directly formed on the display panel 5, and the polarizing function layer 2 is directly formed on the cover 1, the cover 1, the polarizing function layer 2, the touch panel 4, and the display panel 5 can all be combined by one adhesive layer 6, and the thickness of the touch display device 100 can be further reduced.

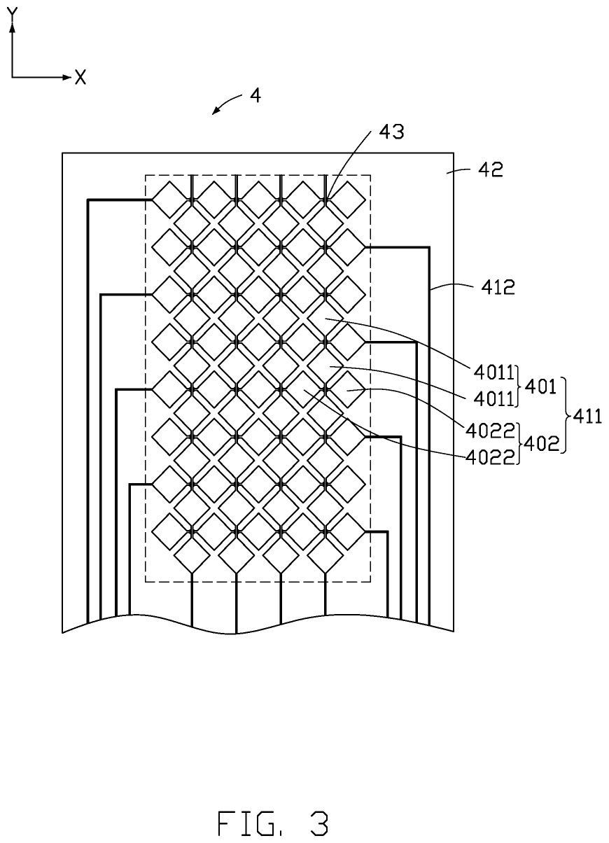

As shown in FIG. 3, the touch sensing layer 41 includes a plurality of sensing electrodes 411 for sensing touch operations and a plurality of traces 412 electrically coupled to the sensing electrodes 411. The sensing electrodes 411 and the traces 412 are both formed on the substrate 42.

In this embodiment, the sensing electrodes 411 include a plurality of first sensing electrode strings 401 and a plurality of second sensing electrode strings 402. The first sensing electrode strings 401 and the second sensing electrode strings 402 are formed on the same surface of the substrate 42 and insulated from each other. The first sensing electrode strings 401 extend in a first direction (Y direction in FIG. 3), and the second sensing electrode strings 402 extend in a second direction (X direction in FIG. 3), the first direction intersects with the second direction. In this embodiment, the first direction is perpendicular to the second direction. In other embodiments, the first sensing electrode strings 401 and the second sensing electrode strings 402 may be disposed in other arrangement.

Each of the first sensing electrode strings 401 includes a plurality of first sensing electrodes 4011, and each of the second sensing electrode strings 402 includes a plurality of second sensing electrodes 4022. The first sensing electrode strings 401 and the second sensing electrode strings 402 are electrically coupled to the traces 412. One of the first sensing electrode 4011 and the second sensing electrode 4022 is a touch driving electrode (Tx), and the other one is a touch sensing electrode (Rx). In this embodiment, the first sensing electrodes 4011 are touch driving electrodes (Tx), the second sensing electrodes 4022 are touch sensing electrodes (Rx), and the first sensing electrodes 4011 and the second sensing electrodes 4022 cooperatively sense touches.

As shown in FIG. 3, in this embodiment, each of the first sensing electrodes 4011 and of the second sensing electrodes 4022 are identical in shape, being diamond-shaped. In other embodiment, each of the first sensing electrodes 4011 and the second sensing electrodes 4022 can also be any other desired shape.

In an embodiment, the sensing electrodes 411 may be made of transparent conductive material, such as at least one of indium tin oxide (ITO), indium zinc oxide (IZO), or aluminum zinc oxide (AZO). In this embodiment, the sensing electrodes 411 are made of ITO.

In an embodiment, each sensing electrode 411 may be in a mesh form, and the sensing electrode 411 may be made of at least one of aluminum (Al), silver (Ag), gold (Au), cobalt (Co), chromium (Cr), copper. (Cu), indium (In), manganese (Mn), molybdenum (Mo), nickel (Ni), niobium (Nd), (pd) palladium, platinum (Pt), titanium (Ti), tungsten (W), zinc (Zn), or an alloy thereof. In an embodiment, the sensing electrodes 411 may be made of poly(3,4-ethylenedioxythiophene) (PEDOT), silver nanowire (AgNW), or carbon nanotube (CNT).

The traces 412 may be made of metal, such as aluminum (Al), silver (Ag), gold (Au), cobalt (Co), chromium (Cr), copper (Cu), Indium (In), Manganese (Mn), Molybdenum (Mo), Nickel (Ni), Niobium (Nd), Palladium (Pd), Platinum (Pt), Titanium (Ti), Tungsten (W), and Zinc (Zn), or alloy thereof.

In the following embodiments, elements having the same or similar functions as those of the first embodiment described by the same reference numerals.

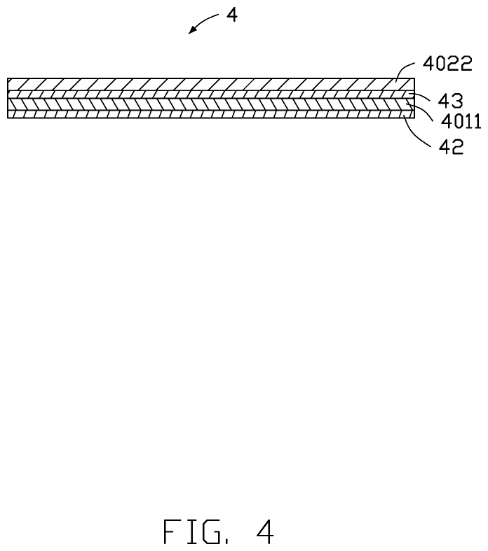

As shown in FIG. 4, the first sensing electrodes 4011 and the second sensing electrodes 4022 of an embodiment may be formed in different layers, and the first sensing electrodes 4011 and the second sensing electrodes 4022 may be insulated from each other by an insulating layer 43.

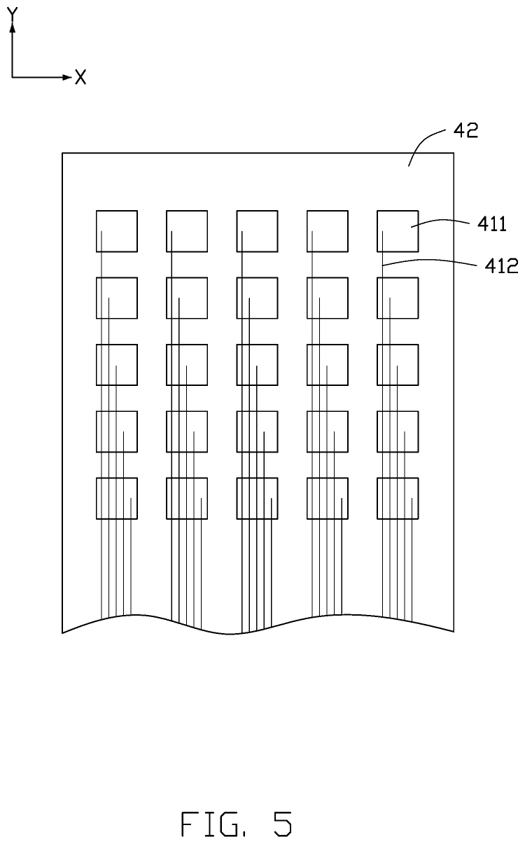

As shown in FIG. 5, a touch panel 4 of an embodiment may be a single-layer self-capacitive touch panel, and sensing electrodes 411 are formed on one surface of the substrate 42 individually. Each of the sensing electrodes 411 is electrically coupled to one trace 412.

The display panel 5 of the present disclosure may be one of any kind of display panels, such as TFT-LED display panel, organic light emitting diode (OLED) display panel, micro-LED display panel, and so on. For example, the display panel 5 may be a flexible OLED display panel, the linear polarizer 21 and the phase retarder 23 both being located on emission side of the OLED display panel for improving the light emitted from the OLED display panel.

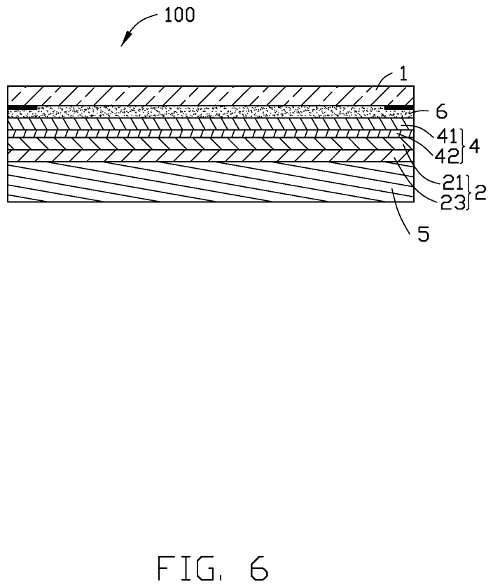

As shown in FIG. 6, in a second embodiment, the polarizing function layer 2 is coated on a surface of the display panel 5. In this embodiment, the polarizing function layer 2 includes a linear polarizer 21 and a phase retarder 23, and the phase retarder 23 is a quarter-wavelength phase retarder. The phase retarder 23 and the linear polarizer 21 are formed by coating a phase retardation material and a polarizing material sequentially on the surface of the display panel 5, and the phase retarder 23 is located between the linear polarizer 21 and the display panel 5. The substrate 42 of the touch panel 4 is located on a side of the polarizing function layer 2 away from the display panel 5, and the touch sensing layer 41 is formed on a side of the substrate 42 away from the display panel 5. The touch display device 100 further includes an adhesive layer 6. The adhesive layer 6 is located between the cover 1 and the touch sensing layer 41.

In this embodiment, the substrate 42 is made of PVDF, its flexibility being better than that of a substrate made by PET, PI, and other materials. In addition, the thickness of the touch panel 4 comprising the substrate 42 made of PVDF is reduced. In this embodiment, the thickness of the touch panel 4 is less than 35 μm. In this embodiment, since the polarizing function layer 2, the substrate 42 of the touch panel 4, and the touch sensing layer 411 are sequentially formed on the on the display panel 5. The cover 1, the polarizing function layer 2, the touch panel 4, and the display panel 5 can be combined by one adhesive layer 6, and the thickness of the touch display device 100 can be further reduced.

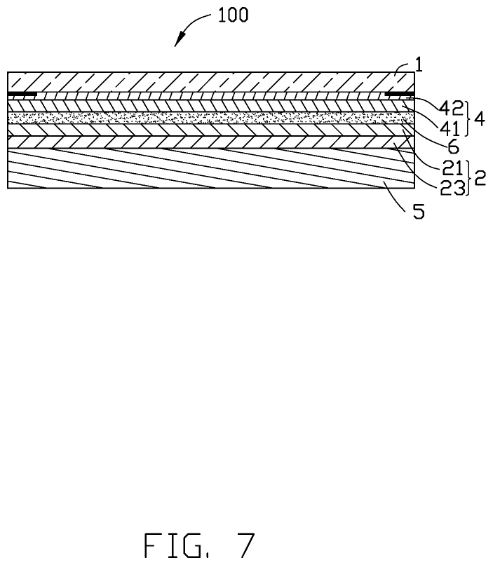

As shown in FIG. 7, in a third embodiment, the phase retarder 23 and the linear polarizer 21 are formed by coating a phase retardation material and a polarizing material sequentially on the surface of the display panel 5, and the phase retarder 23 is located between the linear polarizer 21 and the display panel 5. The substrate 42 of the touch panel 4 is formed on the cover 1, and the touch sensing layer 41 is formed on a side of the substrate 42 away from the cover 1. The touch display device 100 further includes an adhesive layer 6. The adhesive layer 6 is located between the linear polarizer 21 and the touch sensing layer 41.

In this embodiment, the substrate 42 is made of PVDF. In addition, the thickness of the touch panel 4 comprising the substrate 42 made of PVDF is also reduced. In this embodiment, the thickness of the touch panel 4 is less than 35 μm. In this embodiment, since the phase retarder 23 and the linear polarizer 21 are sequentially formed on the on the display panel 5, and the substrate 42 and the touch sensing layer 41 are sequentially formed on the cover 1. The cover 1, the polarizing function layer 2, the touch panel 4, and the display panel 5 can be combined by one adhesive layer 6, and the thickness of the touch display device 100 can be further reduced.

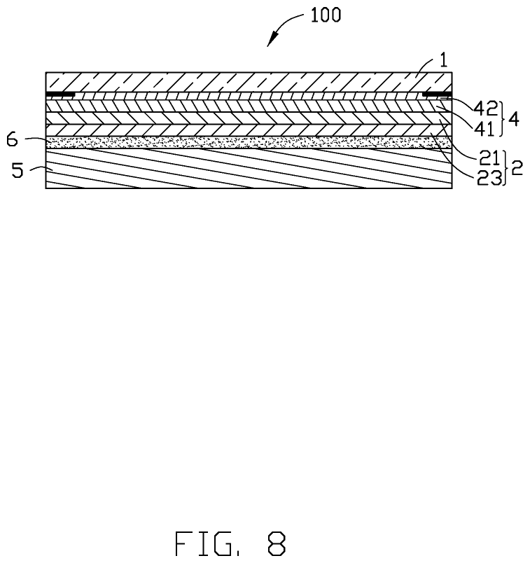

As shown in FIG. 8, in a fourth embodiment, the substrate 42 of the touch panel 4 is coated on the cover 1, and the touch sensing layer 41 is formed on a side of the substrate 42 away from the cover 1. The linear polarizer 21 is coated on a surface of the touch sensing layer 41 away from the cover 1, the phase retarder 23 is coated on a surface of the linear polarizer 21 away from the cover. The touch display device 100 further includes an adhesive layer 6. The adhesive layer 6 is located between the polarizing function layer 2 and the display panel 5.

In this embodiment, the substrate 42 is made of PVDF. In addition, the thickness of the touch panel 4 comprising the substrate 42 made of PVDF is also thin. In this embodiment, the thickness of the touch panel 4 is less than 35 μm. In this embodiment, since the substrate 42, the touch sensing layer 41, the polarizing function layer 2 are sequentially formed on the on the cover 1. The cover 1, the polarizing function layer 2, the touch panel 4, and the display panel 5 can be combined by one adhesive layer 6, and the thickness of the touch display device 100 can be reduced.

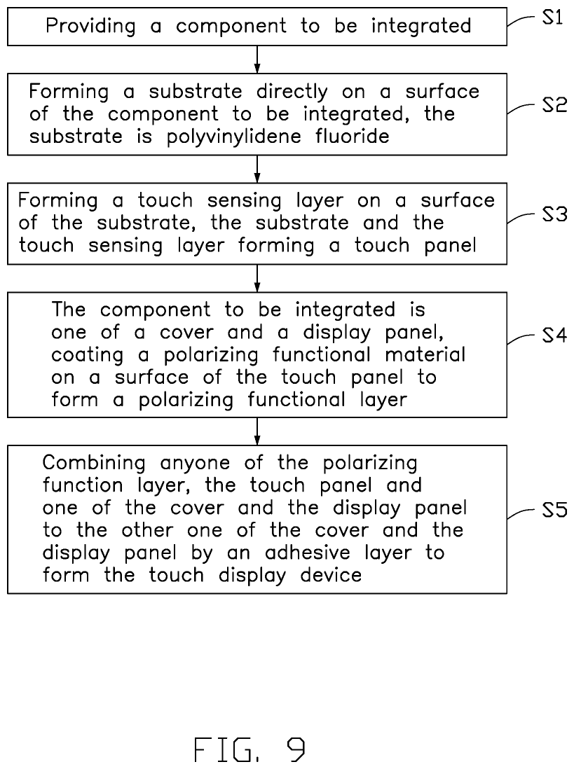

As shown is FIG. 9, a method for making the touch display device 100 of the fourth embodiment comprises:

Step S1: a component to be integrated is provided.

In this embodiment, the cover 1 or the display panel 5 are provided as a component to be integrated. The cover 1 is a flexible substrate that protects the sensing electrodes 411 and the traces 412 of the touch panel 4 of the touch display device 100.

In this embodiment, the display panel 5 further includes upper substrate, lower substrate, and display medium located between the upper substrate and the lower substrate (not shown).

Step S2: a substrate 42 is formed directly on the component to be integrated, the substrate 42 is made of PVDF.

In this embodiment, the substrate 42 is formed directly on a surface of the cover 1 or the display panel 5 (whichever is required).

In this embodiment, the PVDF in the molten state can be formed on the surface of the cover 1 or the display panel 5 by coating, printing, physical vapor deposition (PVD), or chemical vapor deposition (CVD). The PVDF in the molten state can be cured to form the substrate 42 by heating or UV light.

Step S3: a touch sensing layer 41 is formed on a surface of the substrate 42, and the touch sensing layer 41 includes touch electrodes for sensing touches.

Step S4: after the touch panel 4 is formed, a polarizing function material is coated on a surface of the touch panel 4 to form a polarizing functional layer 2.

In this embodiment, the polarizing function material includes a polarizing material and a phase retarding material. The polarizing function layer 2 includes a linear polarizer 21 and a phase retarder 23 stacked sequentially. In one embodiment, the polarizing material may be coated on the surface of the touch panel 4 to form a line polarizer 21, and then the phase retarding material may be coated on a surface of the line polarizer 21 to form a phase retarder 23. In another embodiment, the phase retarding material may be coated on the surface of the touch panel 4 to form a phase retarder 23, and then the polarizing material may be coated on a surface of the phase retarder 23 to form a line polarizer 21.

Step S5: the polarizing function layer 2, the touch panel 4, and the cover 1 or the display panel 5 (as the case may be) may be combined with the other of the cover 1 and the display panel 5 by the adhesive layer 6, thereby forming the touch display device 100 (for example, the touch display device 100 shown in FIG. 8).

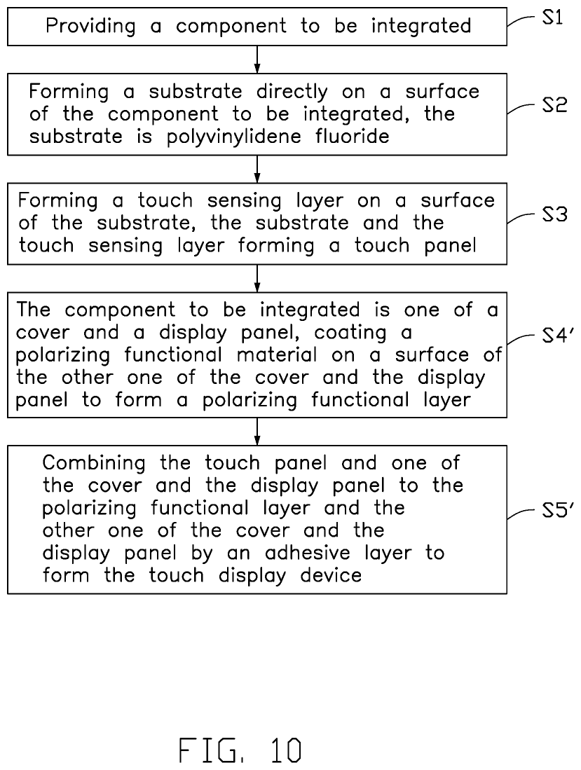

As shown is FIG. 10, in this embodiment, Steps S1 to S3 are the same as steps S1 to S3 of the above-mentioned embodiment, and are not described herein again. A method for making the touch display device 100 of the first or the third embodiment comprises:

Step S4′: a polarizing function material is coated on a surface of the other of the cover 1 and the display panel 5 to form a polarizing functional layer 2.

In this embodiment, the polarizing function material includes a polarizing material and a phase retarding material. The polarizing function layer 2 includes a linear polarizer 21 and a phase retarder 23 stacked sequentially. In one embodiment, the polarizing material may be coated on the surface of the cover 1 or the display panel 5 to form a line polarizer 21, and then the phase retarding material may be coated on a surface of the line polarizer 21 to form a phase retarder 23. In another embodiment, the phase retarding material may be coated on the surface of either the cover 1 or the display panel 5 to form a phase retarder 23, and then the polarizing material may be coated on a surface of the phase retarder 23 to form a line polarizer 21

Step S5′: the touch panel 4 and either the cover 1 or the display panel 5 may be combined to the polarizing function layer 2. The other of the cover 1 and the display panel 5 may receive the adhesive layer 6, thereby forming the touch display device 100 (for example, the touch display device 100 shown in FIG. 2 or FIG. 7).

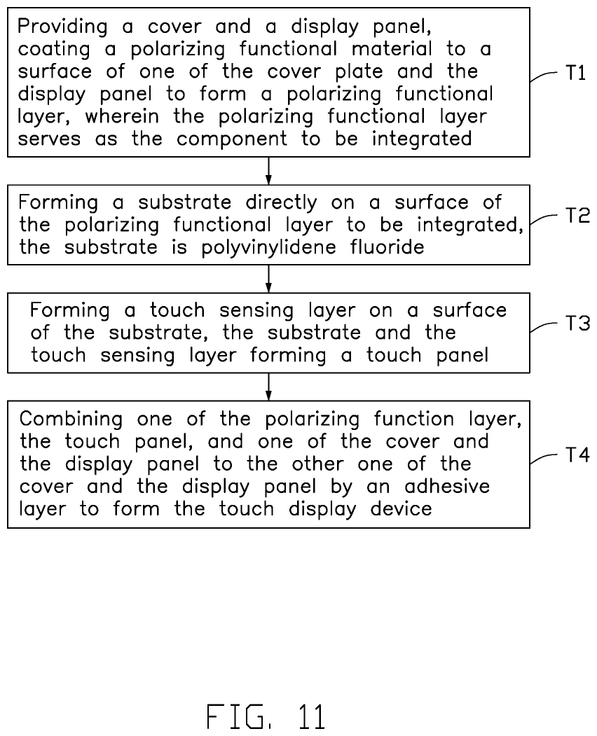

As shown in FIG. 11, a method for making the touch display device 100 of the second embodiment comprises:

Step T1: a cover 1 and a display panel 5 are provided, a polarizing function material being coated on a surface of either the cover 1 or the display 5 to form a polarizing functional layer 2.

In this embodiment, the polarizing functional layer 2 serves as a component to be integrated.

In this embodiment, the polarizing function material includes a polarizing material and a phase retarding material. The polarizing function layer 2 includes a linear polarizer 21 and a phase retarder 23 stacked sequentially. In one embodiment, the polarizing material coating forms a line polarizer 21, and then the phase retarding material may be coated on a surface of the line polarizer 21 to form a phase retarder 23. In another embodiment, the phase retarding material may be coated on the cover 1 or the display 5 to form a phase retarder 23, and then the polarizing material coated on a surface of the phase retarder 23 to form a line polarizer 21.

Step T2: A substrate 42 is formed directly on the polarizing functional layer 2 (whether on the cover 1 or the display 5), the substrate 42 being made of PVDF.

The PVDF in the molten state can be formed on the surface of the polarizing functional layer 2 by coating, printing, physical vapor deposition (PVD), or chemical vapor deposition (CVD). The PVDF in the molten state can be cured to form the substrate 42 by heating or UV light.

Step T3: a touch sensing layer 41 is formed on a surface of the substrate 42, and the substrate 42 and the touch sensing layer 41 cooperatively form a touch panel 4.

In this embodiment, the touch sensing layer 41 can be formed by physical vapor deposition (PVD), chemical vapor deposition (CVD), or a printing process, not being limited to such processes.

Step T4: the polarizing function layer 2, the touch panel 4, and either the cover 1 or the display panel 5 may be combined with the other of the cover 1 and the display panel 5 by the adhesive layer 6, thereby forming the touch display device 100 (for example, the touch display device 100 shown in FIG. 6).

The PVDF of the present disclosure can be coated on a surface of any one of the cover 1, the display panel 5, the linear polarizer 21, and the phase retarder 23, so as to form the substrate 42. The present disclosure only shows components as the cover 1, the display panel 5, the linear polarizer 21, and the phase retarder 23, but the substrate 42 may not be limited to being formed on such components. The PVDF may be coated on other components of the display device 100 to form a substrate 42.

It is to be understood, even though information and advantages of the present embodiments have been set forth in the foregoing description, together with details of the structures and functions of the present embodiments, the disclosure is illustrative only; changes may be made in detail, especially in matters of shape, size, and arrangement of parts within the principles of the present embodiments to the full extent indicated by the plain meaning of the terms in which the appended claims are expressed.

What is claimed is:

1. A touch display device, comprising:
a touch panel;
the touch panel comprises a substrate and a touch sensing layer formed on the substrate;
wherein the substrate is polyvinylidene fluoride.

2. The touch display device of claim 1, wherein the touch display panel further comprises a cover, a polarizing functional layer and a display panel; and
the substrate is directly contact with a surface of one of the cover, the polarizing functional layer and the display panel.

3. The touch display device of claim 2, wherein the polarizing functional layer comprises a linear polarizer and a phase retarder.

4. The touch display device of claim 2, wherein the cover is a flexible substrate.

5. The touch display device of claim 2, wherein the display panel is an organic light emitting diode display panel.

6. The touch display device of claim 1, wherein a thickness of the touch panel is less than 35 μm.

7. The touch display device of claim 2, wherein the polarizing functional layer is directly in contact with a surface of one of the display panel, the cover and the touch panel.

8. A method for making a touch display device, comprising:
providing a component to be integrated.
forming a substrate directly on a surface of the component to be integrated, the substrate is polyvinylidene fluoride.
forming a touch sensing layer on a surface of the substrate, the substrate and the touch sensing layer forming a touch panel.

9. The method of claim 8, wherein the component to be integrated is one of a cover and a display panel; and the method for making the touch display device further comprises:
after forming the touch panel, forming a polarizing function material on a surface of the touch panel to form a polarizing functional layer; and
combining anyone of the polarizing function layer, the touch panel, and one of the cover and the display panel to another one of the cover and the display panel by an adhesive layer to form the touch display device.

10. The method of claim 8, wherein the component to be integrated is one of a cover and a display panel; and the method for making the touch display device further comprises:
forming a polarizing function material on a surface of the other one of the cover and the display panel to form a polarizing functional layer; and
combining the touch panel and one of the cover and the display panel to the polarizing functional layer and the other one of the cover and the display panel by an adhesive layer to form the touch display device.

11. The method of claim 8, wherein the method for making the touch display device further comprises:
providing a cover and a display panel before providing the component to be integrated, forming a polarizing function material on a surface of one of the cover plate and the display panel to form a polarizing functional layer, wherein the polarizing functional layer is the component to be integrated;
after forming the touch panel, combining one of the polarizing function layer, the touch panel, and one of the cover and the display panel to the other one of the cover and the display panel by an adhesive layer to form the touch display device.

12. The method of claim 8, wherein the substrate is formed on the component to be integrated by one of coating, printing, physical vapor deposition, and chemical vapor deposition.

13. The method of claim 9, wherein the polarizing function material is formed on the surface of the touch panel by coating.

14. The method of claim 10, wherein the polarizing function material is formed on the surface of the other one of the cover and the display panel by coating.

15. The method of claim 11, wherein the polarizing function material is formed on the surface of one of the cover plate and the display panel by coating.
